(19) United States
(12) Patent Application Publication
(10) Pub. No.: US 2026/0056268 A1
(43) Pub. Date: Feb. 26, 2026

(54) CURRENT SENSOR

(71) Applicant: Murata Manufacturing Co., Ltd., Nagaokakyo-shi (JP)

(72) Inventor: Kai SHEN, Nagaokakyo-shi (JP)

(21) Appl. No.: 19/377,250

(22) Filed: Nov. 3, 2025

Related U.S. Application Data
(63) Continuation of application No. PCT/JP2024/019065, filed on May 23, 2024.

(30) Foreign Application Priority Data
Jun. 12, 2023 (JP) 2023-096222

(51) Int. Cl. G01R 33/09

(52) U.S. Cl. CPC G01R 33/091; G01R 33/093; G01R 33/096; G01R 33/098

(57) ABSTRACT

A current sensor includes a first busbar, a second busbar, and a third busbar, a first sensor unit, a second sensor unit and a calculating unit. The first, second and third busbars extend in a first direction apart from each other and are arranged in a second direction orthogonal to the first direction. Three-phase alternating currents flow through the first, second and third busbars. The first sensor unit is located between remaining two busbars other than one busbar to be measured among the first, second and third busbars. The second sensor unit measures one of the remaining two busbars other than the one busbar to be measured and is located between the one busbar to be measured and the other one of the remaining two busbars. The calculating unit calculates current values of the first, second and third busbars from output values of the first and second sensor units.

### CROSS REFERENCE TO RELATED APPLICATIONS

This application is a continuation of International Application No. PCT/JP2024/019065, filed May 23, 2024, which claims priority to Japanese Patent Application No. 2023-096222, filed Jun. 12, 2023, the contents of each of which are hereby incorporated by reference in their entirety.

### TECHNICAL FIELD

The present disclosure relates generally to a current sensor.

### BACKGROUND

In general, Japanese Unexamined Patent Application Publication No. 2008-58035 discloses a configuration of a current measurement device. The current measurement device described therein measures current values of three conductors through which a total sum of the currents is zero flow. The current measurement device includes first and second coreless current sensors, a holding unit, a calculating unit, and a shield member. The first and second coreless current sensors are placed in predetermined relative positions with respect to the three conductors. The holding unit acquires and holds a coefficient necessary for measurement of currents flowing through the three conductors in a preparation stage before the measurement. The calculating unit then calculates current values of the currents flowing through the conductors based on output signals of the first and second coreless current sensors and the coefficient held in the holding unit by utilizing the fact that the total sum of the current values of the currents flowing through the three conductors is zero. The shield member surrounds the conductors and the first and second coreless current sensors.

A shield member is provided in the current measurement device described in Japanese Unexamined Patent Application Publication No. 2008-58035. This configuration increases the size of the device and decreases accuracy of measurement of the currents due to influence of the shield member. Furthermore, this device requires complicated calculation since the current values of the conductors are calculated on the basis of the parameter acquired in advance. As a result, this configuration also prolongs a period of calculation of the current values, thereby decreasing responsiveness of current measurement.

### SUMMARY OF THE INVENTION

In view of the above-described problem, it is an object of the exemplary aspects of the present disclosure to provide a current sensor with improved measurement accuracy and responsiveness while an overall size is also reduced.

A current sensor based on the present invention includes a first busbar, a second busbar, and a third busbar, a first sensor unit, a second sensor unit, and a calculating unit. The first busbar, the second busbar, and the third busbar extend in a first direction apart from each other and are arranged in a second direction orthogonal to the first direction, and three-phase alternating currents flow through the first busbar, the second busbar, and the third busbar. The first sensor unit is located between remaining two busbars other than one busbar to be measured among the first busbar, the second busbar, and the third busbar. The second sensor unit measures one of the remaining two busbars other than the one busbar to be measured and is located between the one busbar to be measured and the other one of the remaining two busbars other than the one busbar to be measured. The calculating unit calculates current values of the first busbar, the second busbar, and the third busbar from output values of the first sensor unit and the second sensor unit. The first sensor unit includes a first magnetism detection element and a second magnetism detection element. The first magnetism detection element and the second magnetism detection element each have a sensitivity axis along a third direction orthogonal to the first direction and the second direction, are arranged in the second direction, and detect magnetic fields generated by currents flowing through the first busbar, the second busbar, and the third busbar. The second sensor unit includes a third magnetism detection element and a fourth magnetism detection element. The third magnetism detection element and the fourth magnetism detection element each have a sensitivity axis along the third direction, are arranged in the second direction, and detect magnetic fields generated by the currents flowing through the first busbar, the second busbar, and the third busbar. A distance between the first magnetism detection element and the one of the remaining two busbars other than the one busbar to be measured and a distance between the second magnetism detection element and the other one of the remaining two busbars other than the one busbar to be measured are substantially equal when viewed in the first direction. A distance between the third magnetism detection element and the other one of the remaining two busbars other than the one busbar to be measured and a distance between the fourth magnetism detection element and the one busbar to be measured are substantially equal when viewed in the first direction. The calculating unit is configured to calculate a current value of a current flowing through the one busbar to be measured based on a differential output value between a measurement value of the first magnetism detection element of the first sensor unit and a measurement value of the second magnetism detection element of the first sensor unit. Moreover, the calculating unit is configured to calculate a current value of a current flowing through the one of the remaining two busbars other than the one busbar to be measured on the basis of a differential output value between a measurement value of the third magnetism detection element of the second sensor unit and a measurement value of the fourth magnetism detection element of the second sensor unit. Furthermore, the calculating unit is configured to calculate a current value of a current flowing through the other one of the remaining two busbars other than the one busbar to be measured by adding up the current value of the current flowing through the one busbar to be measured and the current value of the current flowing through the one of the remaining two busbars other than the one busbar to be measured.

According to the exemplary aspects of the present disclosure described in detail below, measurement accuracy and responsiveness are improved while an overall size of a current sensor is also reduced.

### BRIEF DESCRIPTION OF DRAWINGS

FIG. 1 is a perspective view illustrating a configuration of a current sensor according to a first exemplary embodiment of the present disclosure.

FIG. 2 is a cross-sectional view illustrating the configuration of the current sensor according to the first exemplary embodiment of the present disclosure.

FIG. 3 is a block diagram illustrating electrical connection among constituent elements in the current sensor according to the first exemplary embodiment of the present disclosure.

FIG. 4 is a cross-sectional view illustrating a state in which a magnetic field generated from each busbar is detected by a first magnetism detection element of a first sensor unit in the current sensor according to the first exemplary embodiment of the present disclosure.

FIG. 5 is a cross-sectional view illustrating a state in which a magnetic field generated from each busbar is detected by a second magnetism detection element of the first sensor unit in the current sensor according to the first exemplary embodiment of the present disclosure.

FIG. 6 is a circuit diagram schematically illustrating a circuit configuration of the current sensor according to the first exemplary embodiment of the present disclosure.

FIG. 7 is a cross-sectional view illustrating a configuration of a current sensor according to a second exemplary embodiment of the present disclosure.

### DETAILED DESCRIPTION OF EMBODIMENTS

Current sensors according to exemplary embodiments of the present disclosure are described below with reference to the drawings. In the description of the exemplary embodiments below, identical or corresponding parts in the drawings are given identical reference signs, and repeated description thereof is omitted.

In the drawings, a direction in which busbars are arranged is referred to as an X direction, which is a second direction, a direction in which the busbars extend is referred to as a Y direction, which is a first direction, and a direction along a sensitivity axis of each magnetism detection element is referred to as a Z direction, which is a third direction. A distance between constituent elements in the current sensor is a distance generally connecting centers of the constituent elements.

### First Exemplary Embodiment

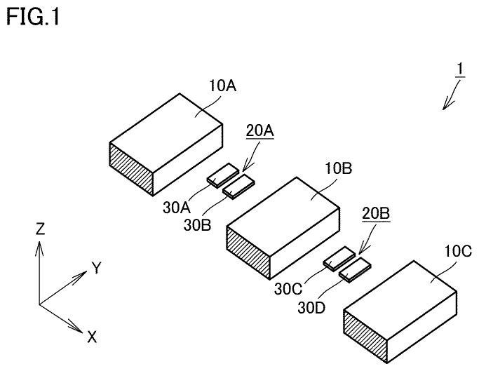

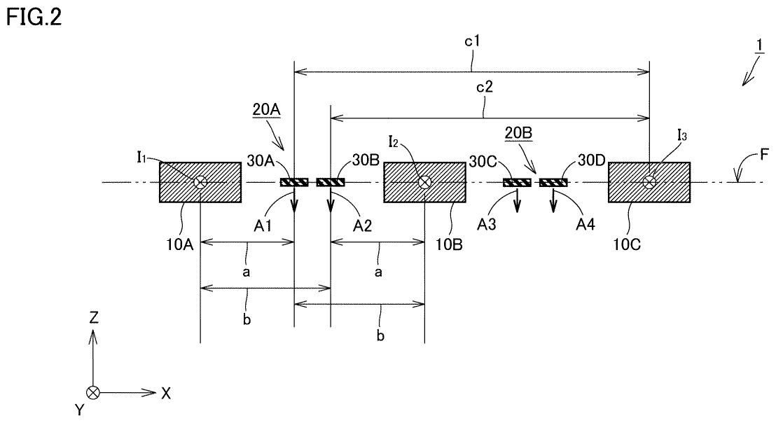

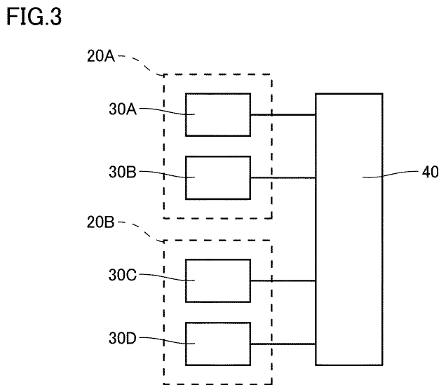

FIG. 1 is a perspective view illustrating a configuration of a current sensor according to a first exemplary embodiment of the present disclosure. FIG. 2 is a cross-sectional view illustrating a configuration of a current sensor according to the first exemplary embodiment. FIG. 3 is a block diagram illustrating electrical connection among constituent elements in the current sensor according to the first exemplary embodiment.

As illustrated in FIGS. 1 to 3, the current sensor 1 according to the first exemplary embodiment includes a first busbar 10A, a second busbar 10B, a third busbar 10C, a first sensor unit 20A, a second sensor unit 20B, and a calculating unit 40, which is shown in FIG. 3.

In the exemplary aspect, the first busbar 10A, the second busbar 10B, and the third busbar 10C are three-phase three-wire busbars. A three-phase alternating current flows through each of the first busbar 10A, the second busbar 10B, and the third busbar 10C. The currents flowing through the first busbar 10A, the second busbar 10B, and the third busbar 10C are alternating currents having equal amplitudes and phases that are different from each other by 120 degrees.

A current value (I₁) of a first current flowing through the first busbar 10A in the first direction (Y direction), a current value (I₂) of a second current flowing through the second busbar 10B in the first direction (Y direction), and a current value (I₃) of a third current flowing through the third busbar 10C in the first direction (Y direction) satisfy a relationship I₁+I₂+I₃=0. For example, the first current may be a U-phase alternating current, the second current may be a V-phase alternating current, and the third current may be a W-phase alternating current.

The first busbar 10A, the second busbar 10B, and the third busbar 10C are arranged apart from each other in the second direction (X direction) orthogonal to the first direction (Y direction). In the present embodiment, a distance between the second busbar 10B and the third busbar 10C and a distance between the first busbar 10A and the second busbar 10B are equal in the second direction (X direction). However, it is noted that the distance between the first busbar 10A and the second busbar 10B and the distance between the second busbar 10B and the third busbar 10C may be different in the second direction (X direction).

As shown, the first busbar 10A extends linearly along the first direction (Y direction). The current value (I₁) of the first current flowing through the first busbar 10A is an alternating current and therefore can take a positive value or a negative value.

The second busbar 10B extends linearly along the first direction (Y direction). The current value (I₂) of the second current flowing through the second busbar 10B is an alternating current and therefore can take a positive value or a negative value.

The third busbar 10C extends linearly along the first direction (Y direction). The current value (I₃) of the third current flowing through the third busbar 10C is an alternating current and therefore can take a positive value or a negative value.

The first sensor unit 20A is located between remaining two busbars other than one busbar to be measured among the first busbar 10A, the second busbar 10B, and the third busbar 10C. In the present embodiment, the first sensor unit 20A is configured to measure the third busbar 10C as the one busbar to be measured. Accordingly, the first sensor unit 20A is located between the first busbar 10A and the second busbar 10B. The first sensor unit 20A is, for example, provided on a substrate (not illustrated). It is noted that the position of the first sensor unit 20A may be fixed with the use of resin mold or the like.

The first sensor unit 20A includes a first magnetism detection element 30A and a second magnetism detection element 30B. The first magnetism detection element 30A and the second magnetism detection element 30B are configured to detect magnetic fields generated by currents flowing through the first busbar 10A, the second busbar 10B, and the third busbar 10C.

In this exemplary aspect, the first magnetism detection element 30A and the second magnetism detection element 30B each have a sensitivity axis along the third direction (Z direction) orthogonal to the first direction (Y direction) and the second direction (X direction). Specifically, the first magnetism detection element 30A has a first sensitivity axis A1 along the third direction (Z direction). The second magnetism detection element 30B has a second sensitivity axis A2 along the third direction (Z direction).

The first magnetism detection element 30A and the second magnetism detection element 30B are arranged in the second direction (X direction). In the present embodiment, the first magnetism detection element 30A and the second magnetism detection element 30B are located at substantially same positions in the third direction (Z direction) and are arranged in the second direction (X direction).

The second sensor unit 20B is configured to measure one of the remaining two busbars other than the one busbar to be measured. In the present embodiment, the second sensor unit 20B is configured to measure the first busbar 10A as the one of the remaining two busbars other than the one busbar to be measured.

The second sensor unit 20B is located between the one busbar to be measured and the other one of the remaining two busbars other than the one busbar to be measured. In the present embodiment, the second sensor unit 20B is located between the third busbar 10C and the second busbar 10B, which is the other one of the remaining two busbars other than the one busbar to be measured. The second sensor unit 20B is, for example, provided on the substrate (not illustrated). It is again noted that the position of the second sensor unit 20B may be fixed by resin mold or the like.

The second sensor unit 20B includes a third magnetism detection element 30C and a fourth magnetism detection element 30D. The third magnetism detection element 30C and the fourth magnetism detection element 30D are configured to detect the magnetic fields generated by the currents flowing through the first busbar 10A, the second busbar 10B, and the third busbar 10C.

The third magnetism detection element 30C and the fourth magnetism detection element 30D each have a sensitivity axis along the third direction (Z direction). Specifically, the third magnetism detection element 30C has a third sensitivity axis A3 along the third direction (Z direction). The fourth magnetism detection element 30D has a fourth sensitivity axis A4 along the third direction (Z direction).

The third magnetism detection element 30C and the fourth magnetism detection element 30D are arranged in the second direction (X direction). In the present embodiment, the third magnetism detection element 30C and the fourth magnetism detection element 30D are located at substantially same positions in the third direction (Z direction) and are arranged in the second direction (X direction).

At least one of the first magnetism detection element 30A, the second magnetism detection element 30B, the third magnetism detection element 30C, and the fourth magnetism detection element 30D in the first sensor unit 20A and the second sensor unit 20B may have a circuit including at least two magneto resistance elements. Alternatively, each of the first magnetism detection element 30A, the second magnetism detection element 30B, the third magnetism detection element 30C, and the fourth magnetism detection element 30D may have a circuit including at least two magneto resistance elements. The circuit including at least two magneto resistance elements may be a half-bridge circuit including two magneto resistance elements or may be a Wheatstone bridge circuit including four magneto resistance elements.

The magneto resistance elements may be any of tunnel magneto resistance (TMR) elements, giant magneto resistance (GMR) elements, or anisotropic magnetic resistance (AMR) elements.

At least one of the first magnetism detection element 30A, the second magnetism detection element 30B, the third magnetism detection element 30C, and the fourth magnetism detection element 30D may have a Hall element. Alternatively, each of the first magnetism detection element 30A, the second magnetism detection element 30B, the third magnetism detection element 30C, and the fourth magnetism detection element 30D may have a Hall element.

As further shown, each of the first busbar 10A, the second busbar 10B, the third busbar 10C, the first sensor unit 20A, and the second sensor unit 20B is placed (e.g., disposed or physically positioned) on a virtual plane F along the first direction (Y direction) and the second direction (X direction).

The calculating unit 40 is configured to calculate current values of the first busbar 10A, the second busbar 10B, and the third busbar 10C from output values of the first sensor unit 20A and the second sensor unit 20B.

As illustrated in FIG. 3, the first sensor unit 20A and the second sensor unit 20B are each electrically connected to the calculating unit 40 by a wire. Specifically, each of the first magnetism detection element 30A, the second magnetism detection element 30B, the third magnetism detection element 30C, and the fourth magnetism detection element 30D is electrically connected to the calculating unit 40.

A positional relationship between the busbars and the magnetism detection elements in the sensor units is described below.

As illustrated in FIG. 2, a distance a between the first magnetism detection element 30A and the first busbar 10A (the one of the remaining two busbars other than the one busbar to be measured) and a distance a between the second magnetism detection element 30B and the second busbar 10B (the other one of the remaining two busbars other than the one busbar to be measured) are substantially equal when viewed in the first direction (Y direction). For purposes of this disclosure, it is noted that the term “substantially equal distances” in the present embodiment includes variations in assembly positions that occur and/or result in a manufacturing process for assembling the constituent elements of the current sensor.

A distance b between the first magnetism detection element 30A and the second busbar 10B (the other one of the remaining two busbars other than the one busbar to be measured) and a distance b between the second magnetism detection element 30B and the first busbar 10A (the one of the remaining two busbars other than the one busbar to be measured) are substantially equal when viewed in the first direction (Y direction).

Since the distance b is obtained by adding a distance between the first magnetism detection element 30A and the second magnetism detection element 30B to the distance a, the distance b between the first magnetism detection element 30A and the second busbar 10B and the distance b between the second magnetism detection element 30B and the first busbar 10A are substantially equal naturally, as long as the distance a between the first magnetism detection element 30A and the first busbar 10A and the distance a between the second magnetism detection element 30B and the second busbar 10B are substantially equal.

The first magnetism detection element 30A and the third busbar 10C (the one busbar to be measured) are arranged at a distance c1 from each other when viewed in the first direction (Y direction). Furthermore, the second magnetism detection element 30B and the third busbar 10C (the one busbar to be measured) are arranged at a distance c2 from each other when viewed in the first direction (Y direction).

Regarding the third magnetism detection element 30C and the fourth magnetism detection element 30D, a distance between the third magnetism detection element 30C and the second busbar 10B (the other one of the remaining two busbars other than the one busbar to be measured) and a distance between the fourth magnetism detection element 30D and the third busbar 10C (the one busbar to be measured) are substantially equal when viewed in the first direction (Y direction).

A distance between the third magnetism detection element 30C and the third busbar 10C (the one busbar to be measured) and a distance between the fourth magnetism detection element 30D and the second busbar 10B (the other one of the remaining two busbars other than the one busbar to be measured) are substantially equal when viewed in the first direction (Y direction).

Distances of the third magnetism detection element 30C and the fourth magnetism detection element 30D from the first busbar 10A (the one of the remaining two busbars other than the one busbar to be measured) are different when viewed in the first direction (Y direction).

In the present embodiment, a magnetism shield plate made of a material such as a high-permeability magnetic material and a magnetic core made of a material such as a soft magnetic material for concentrating a magnetic field are not provided between any busbar and any sensor unit. This configuration reduces the overall size of the current sensor 1 according to the present embodiment.

The following describes that only a current value of a busbar to be measured can be measured even in a case where a magnetic field including busbars other than the busbar to be measured is detected by each sensor unit.

In the present embodiment, the first sensor unit 20A is configured to measure the current value (I₃) of the current flowing through the third busbar 10C. The second sensor unit 20B is configured to measure the current value (I₁) of the current flowing through the first busbar 10A. The current value (I₂) of the current flowing through the second busbar 10B is calculated from the current values measured by the first sensor unit 20A and the second sensor unit 20B. An embodiment when the current value I₃ of the current flowing through the third busbar 10C is measured by the first sensor unit 20A is described as an example regarding measurement of a current value of a current flowing through a corresponding busbar by each sensor unit.

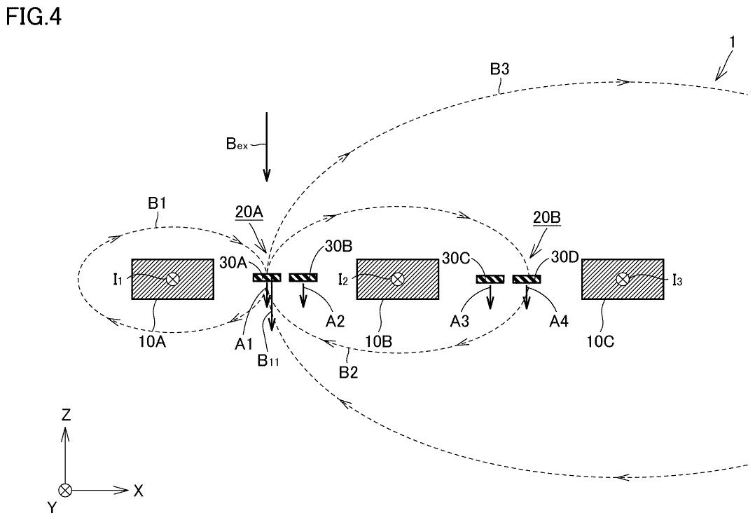

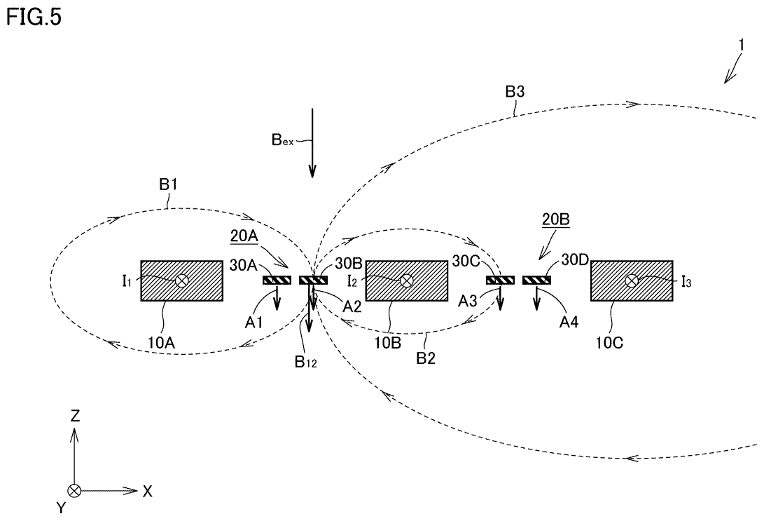

FIG. 4 is a cross-sectional view illustrating a state in which a magnetic field generated from each busbar is detected by the first magnetism detection element of the first sensor unit in the current sensor according to the first exemplary embodiment. FIG. 5 is a cross-sectional view illustrating a state in which a magnetic field generated from each busbar is detected by the second magnetism detection element of the first sensor unit in the current sensor according to the first exemplary embodiment.

First, as illustrated in FIG. 4, a magnetic field B₁₁ detected by the first magnetism detection element 30A is a sum of magnetic fields generated from the busbars and an external magnetic field. When the first current flows, a first magnetic field B1 is generated around the first busbar 10A. When the second current flows, a second magnetic field B2 is generated around the second busbar 10B. When the third current flows, a third magnetic field B3 is generated around the third busbar 10C. Furthermore, an external magnetic field Bₑₓ is generated due to external influence. Accordingly, the magnetic field Bu detected by the first magnetism detection element 30A is expressed as B₁₁=B1+B2+B3+Bₑₓ.

As illustrated in FIGS. 2 and 4, the first magnetic field B1 is expressed as B1=μ(1/2πa)I₁ by using magnetic permeability u and the distance a from a relationship between a magnetic flux density and an intensity of a magnetic field. According to the exemplary aspect, it is assumed that μ(1/2π) is a constant k in the above expression, the first magnetic field B1 is expressed as B1=(k/a)I₁.

Similarly, in a case where the second magnetic field B2 of the second busbar 10B is detected by the first magnetism detection element 30A, the second magnetic field B2 is expressed as B2=μ(1/2πb)I₂. In the exemplary aspect, it is assumed that μ(1/2π) is a constant k, and the second magnetic field B2 is expressed as B2=(k/b)I₂. In a case where the third magnetic field B3 of the third busbar 10C is detected by the first magnetism detection element 30A, the third magnetic field B3 is expressed as B3=μ(1/2πc1)I₃. It is assumed that μ(1/2π) is a constant k, and the third magnetic field B3 is expressed as B3=(k/c1)I₃.

The magnetic field Bu detected by the first magnetism detection element 30A is expressed by the expression (1) by assigning the above expressions to B₁₁=B1+B2+B3+Bₑₓ, for example, in a case where a direction in which the first sensitivity axis A1 is directed is a positive direction. As illustrated in FIGS. 2 and 5, a magnetic field B₁₂ of the second magnetism detection element 30B is expressed by the expression (2), similarly to the case of the first magnetism detection element 30A.

$$\begin{matrix}[ Math . 1 ] & \\ {B}_{11} = \frac{k}{a} {I}_{1} - \frac{k}{b} {I}_{2} - \frac{k}{c 1} {I}_{3} + {B}_{e x} & ( 1 )\end{matrix}$$

$${B}_{12} = \frac{k}{b} {I}_{1} - \frac{k}{a} {I}_{2} - \frac{k}{c 2} {I}_{3} + {B}_{ex} \qquad ( 2 )$$

In the first sensor unit 20A, a measurement value of the magnetic field Bu detected by the first magnetism detection element 30A and a measurement value of the magnetic field B₁₂ detected by the second magnetism detection element 30B can be processed by the calculating unit 40. Specifically, the calculating unit 40 can be configured to calculate the current value of the current flowing through the third busbar 10C (the one busbar to be measured) on the basis of a differential output value between the measurement value of the first magnetism detection element 30A and the measurement value of the second magnetism detection element 30B in the first sensor unit 20A. The current value I₃ of the third current flowing through the third busbar 10C is calculated by the following expression.

$$\begin{matrix}[ Math . 2 ] & \\ \begin{matrix}{B}_{11} - {B}_{12} = \frac{k}{a} {I}_{1} - \frac{k}{b} {I}_{2} - \frac{k}{c 1} {I}_{3} + {B}_{ex} - \frac{k}{b} {I}_{1} + \frac{k}{a} {I}_{2} + \frac{k}{c 2} {I}_{3} - {B}_{ex} & ( 3 ) \\ = k ( \frac{b}{ab} {I}_{1} - \frac{a}{a b} {I}_{2} - \frac{c 2}{c 1 c 2} {I}_{3} - \frac{a}{ab} {I}_{1} + \frac{b}{ab} {I}_{2} + \frac{c 1}{c 1 c 2} {I}_{3} ) & \\ = k ( \frac{b - a}{a b} {I}_{1} + \frac{b - a}{a b} {I}_{2} + \frac{c 1 - c 2}{c 1 c 2} {I}_{3} ) & \\ = k ( \frac{b - a}{ab} {I}_{1} + \frac{b - a}{a b} {I}_{2} + \frac{b - a}{c 1 c 2} {I}_{3} ) & \\ = k ( b - a ) ( \frac{1}{a b} {I}_{1} + \frac{1}{a b} {I}_{2} + \frac{1}{c 1 c 2} {I}_{3} ) & ( 4 ) \\ = k ( b - a ) ( \frac{2}{ab} ( {I}_{1} + {I}_{2} ) + \frac{1}{c 1 c 2} {I}_{3} ) & \\ = k ( b - a ) ( \frac{1}{a b} ( - {I}_{3} ) + \frac{1}{c 1 c 2} {I}_{3} ) & \\ = k ( b - a ) ( \frac{1}{c 1 c 2} - \frac{1}{a b} ) {I}_{3} & \end{matrix} & \end{matrix}$$

$${B}_{11} - {B}_{12} ∝ {I}_{3} \qquad ( 5 )$$

$$∴ {V}_{1} ∝ {I}_{3}$$

Since the differential output value between the measurement value of the first magnetism detection element 30A and the measurement value of the second magnetism detection element 30B is calculated, the external magnetic fields Bₑₓ measured by the first magnetism detection element 30A and the second magnetism detection element 30B cancel out each other. Furthermore, (c1−c2) expressed as a coefficient of the current value I₃ is equal to (b−a) in view of the positional relationship of the first magnetism detection element 30A relative to the busbars. Accordingly, a current value of each busbar can be expressed by an expression including (b−a) as a coefficient by replacing (c1−c2) with (b−a), as indicated by the above expression (3).

Furthermore, the currents flowing through the busbars are three-phase alternating currents and satisfy the relationship I₁+I₂+I₃=0 according to the exemplary aspect. Accordingly, by using I₁+I₂=−I₃ in the above expression, the expression (4) is satisfied.

According to the above expression, by calculating the differential output value between the measurement value of the first magnetism detection element 30A and the measurement value of the second magnetism detection element 30B in the first sensor unit 20A, a difference between the measurement value of the first magnetism detection element 30A and the measurement value of the second magnetism detection element 30B can be expressed by a value obtained by multiplexing the current value Is of the third current flowing through the third busbar 10C by a coefficient. Since the difference between the measurement value of the first magnetism detection element 30A and the measurement value of the second magnetism detection element 30B, that is, a measurement value V₁ detected and calculated in the first sensor unit 20A can be expressed as being proportional to the current value Is as indicated by the expression (5), the current value Is of the current flowing through the third busbar 10C can be measured by the first sensor unit 20A.

In the second sensor unit 20B, a measurement value of a magnetic field detected by the third magnetism detection element 30C and a measurement value of a magnetic field detected by the fourth magnetism detection element 30D are processed by the calculating unit 40. Specifically, the current value of the current flowing through the first busbar 10A (the one of the remaining two busbars other than the one busbar to be measured) can be calculated on the basis of a differential output value between the measurement value of the third magnetism detection element 30C and the measurement value of the fourth magnetism detection element 30D in the second sensor unit 20B.

The current value of the current flowing through the first busbar 10A is calculated by a similar calculation method used for the first sensor unit 20A. Since a measurement value V₂ detected and calculated in the second sensor unit 20B can be expressed as being proportional to the current value I₁ as indicated by the following expression (6), the current value I₁ of the current flowing through the first busbar 10A can be measured by the second sensor unit 20B.

$$\begin{matrix}[ Math . 3 ] & \\ {V}_{2} ∝ {I}_{1} & ( 6 )\end{matrix}$$

Furthermore, the calculating unit 40 can be configured to calculate the current value of the current flowing through the other one of the remaining two busbars other than the one busbar to be measured by adding up the current value I₃ of the current flowing through the third busbar 10C (the one busbar to be measured) and the current value I₁ of the current flowing through the first busbar 10A (the one of the remaining two busbars other than the one busbar to be measured).

Specifically, the following expression (7) can be obtained by using the relationship I₁+I₂+I₃=0 by adding up the measurement value V₁ detected and calculated in the first sensor unit 20A and the measurement value V₂ detected and calculated in the second sensor unit 20B by the calculating unit 40. Therefore, the current value I₂ of the current flowing through the second busbar 10B can be calculated from the measurement value V₁ detected and calculated in the first sensor unit 20A and the measurement value V₂ detected and calculated in the second sensor unit 20B.

$$\begin{matrix}[ Math . 4 ] & \\ {V}_{1} + {V}_{2} ∝ {I}_{3} + {I}_{1} & ( 7 )\end{matrix}$$

$$∴ {V}_{1} + {V}_{2} ∝ {I}_{2}$$

As described above, in the present embodiment, by measuring the magnetic fields of the first busbar 10A, the second busbar 10B, and the third busbar 10C by the first sensor unit 20A and the second sensor unit 20B, the current value I₃ of the current flowing through the third busbar 10C can be calculated on the basis of the measurement value of the magnetic field measured by the first sensor unit 20A, the current value I₁ of the current flowing through the first busbar 10A can be calculated on the basis of the measurement value of the magnetic field measured by the second sensor unit 20B, and the current value I₂ flowing through the second busbar 10B can be calculated on the basis of the calculated current value I₃ and current value I₁. This configuration enables current values of the three-phase alternating-current busbars to be measured without providing a shield between the busbars.

Next, a circuit configuration of the current sensor 1 according to the present embodiment is described, but the circuit configuration of the current sensor 1 according to the present embodiment is not limited to the following configuration.

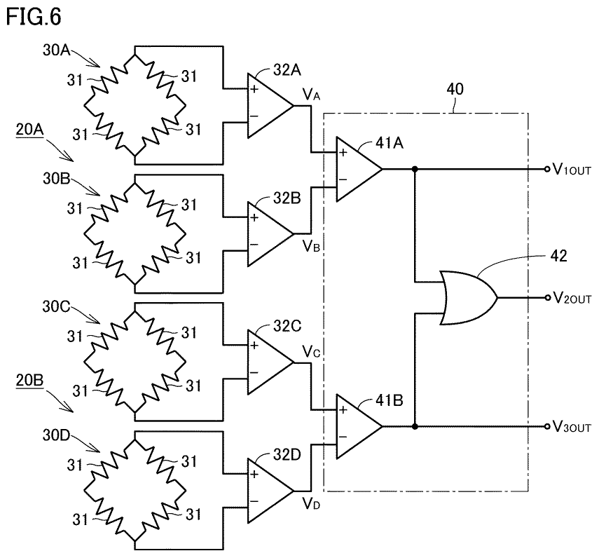

FIG. 6 is a circuit diagram schematically illustrating the circuit configuration of the current sensor according to the first exemplary embodiment. As illustrated in FIG. 6, in the present embodiment, the first magnetism detection element 30A, the second magnetism detection element 30B, the third magnetism detection element 30C, and the fourth magnetism detection element 30D each include a Wheatstone bridge circuit including four tunnel magneto resistance elements 31.

In this aspect, the detection signal of the first magnetism detection element 30A is output as a first voltage signal indicative of a first output value (V_{A}) via a first amplifier 32A. The detection signal of the second magnetism detection element 30B is output as a second voltage signal indicative of a second output value (V_{B}) via a second amplifier 32B. The detection signal of the third magnetism detection element 30C is output as a third voltage signal indicative of a third output value (V_{C}) via a third amplifier 32C. The detection signal of the fourth magnetism detection element 30D is output as a fourth voltage signal indicative of a fourth output value (V_{D}) via a fourth amplifier 32D. The first amplifier 32A, the second amplifier 32B, the third amplifier 32C, and the fourth amplifier 32D are operational amplifiers that perform differential amplification.

The calculating unit 40 is an analog circuit in which circuit elements such as an amplifier are connected. The calculating unit 40 receives the first voltage signal indicative of the first output value (V_{A}), the second voltage signal indicative of the second output value (V_{B}), the third voltage signal indicative of the third output value (V_{C}), and the fourth voltage signal indicative of the fourth output value (V_{D}), and outputs a first output voltage signal (V_{1OUT}) corresponding to the current (detection) value (I₃) of the third current, a second output voltage signal (V_{2OUT}) corresponding to the current (detection) value (I₂) of the second current, and a third output voltage signal (V_{3OUT}) corresponding to the current (detection) value (I₁) of the first current in response to these input signals.

The calculating unit 40 includes a first differential amplifier 41A, a second differential amplifier 41B, and a summing amplifier 42.

The first voltage signal indicative of the first output value (V_{A}) is input to a non-inverting input terminal (+) of the first differential amplifier 41A, and the second voltage signal indicative of the second output value (V_{B}) is input to an inverting input terminal (−) of the first differential amplifier 41A. The first differential amplifier 41A outputs the first output voltage signal (V_{1OUT}). In the present embodiment, the above expression (5) holds, and therefore the calculating unit 40 can output the first output voltage signal (V_{1OUT}) as a voltage signal corresponding to the current (detection) value (I₃) of the third current.

The third voltage signal indicative of the third output value (V_{C}) is input to a non-inverting input terminal (+) of the second differential amplifier 41B, and the fourth voltage signal indicative of the fourth output value (V_{D}) is input to an inverting input terminal (−) of the second differential amplifier 41B. The second differential amplifier 41B outputs the third output voltage signal (V_{3OUT}). In the present embodiment, the above expression (6) holds, and therefore the calculating unit 40 can output the third output voltage signal (V_{3OUT}) as a voltage signal corresponding to the current (detection) value (I₁) of the first current.

To the summing amplifier 42, the first output voltage signal (V_{1OUT}) and the third output voltage signal (V_{3OUT}) are input. The summing amplifier 42 is then configured to output the second output voltage signal (V_{2OUT}). In the present embodiment, the above expression (7) holds, and therefore the calculating unit 40 is configured to output the second output voltage signal (V_{2OUT}) as a voltage signal corresponding to the current (detection) value (I₂) of the second current.

In the current sensor 1 according to the first exemplary embodiment, the first sensor unit 20A and the second sensor unit 20B each including two magnetism detection elements are placed between three-phase alternating-current busbars to measure the three-phase alternating-current busbars. The two magnetism detection elements are placed so that a distance between one of the magnetism detection elements and one of the remaining two busbars other than the busbar to be measured and a distance between the other one of the magnetism detection elements and the other one of the remaining two busbars other than the busbar to be measured are substantially equal. Magnetic fields generated from currents flowing through the busbars are detected by the two magnetism detection elements, and a differential output value between the current values measured by the two magnetism detection elements is calculated by the calculating unit 40. In this way, a measurement value of a magnetic field detected in each sensor unit can be expressed only by a value proportional to a current value of a busbar to be measured among the busbars. Current values of the two busbars to be measured are measured by the two sensor units. A measurement value of remaining one busbar is calculated from the current values measured by the sensor units on the basis of the relationship among the three-phase alternating currents. Since a measurement value in each sensor unit can be expressed only by a current value to be measured without using a shield member that blocks an external magnetic field while canceling influence of the external magnetic field, preparations such as measuring current values of the busbars and acquiring a parameter in advance are not needed. Furthermore, complicated calculation based on the parameter is not needed. As a result, measurement accuracy and responsiveness is improved while an overall size of the current sensor 1 is also reduced.

In the current sensor 1 according to the first exemplary embodiment, it is unnecessary to provide a shield member that blocks an external magnetic field for each busbar and each sensor unit. As a result, the configuration is made simpler and the current sensor can be reduced in cost as compared with a case where a shield member is provided.

In the current sensor 1 according to the first exemplary embodiment, measurement accuracy and responsiveness is improved while an overall size of the current sensor 1 is reduced by using a TMR element, a GMR element, an AMR element, or a Hole element.

In the current sensor 1 according to the first exemplary embodiment, the current sensor 1 that is reduced in height in a height direction can be provided by arranging busbars and sensor units on one plane.

### Second Exemplary Embodiment

A current sensor according to a second exemplary embodiment of the present disclosure is described below with reference to the drawings. The current sensor according to Embodiment 2 is different from the current sensor 1 according to the first exemplary embodiment in position of a second sensor unit, and, therefore, a description of a configuration similar to that of the current sensor 1 according to the first exemplary embodiment is not repeated herein.

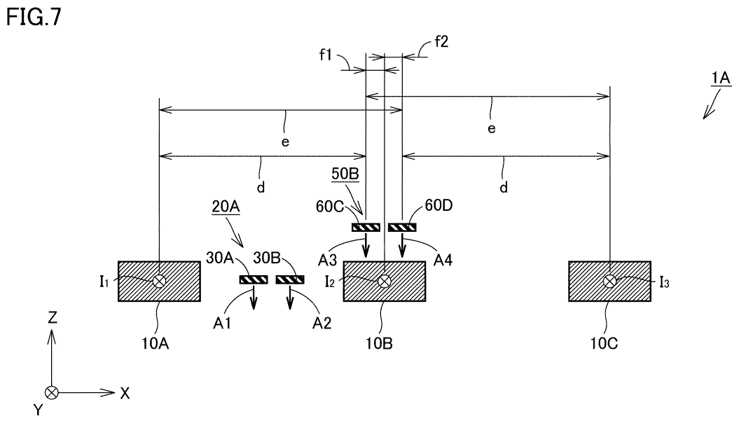

FIG. 7 is a cross-sectional view illustrating a configuration of the current sensor according to the second exemplary embodiment. As illustrated in FIG. 7, the current sensor 1A according to the second exemplary embodiment includes a first busbar 10A, a second busbar 10B, a third busbar 10C, a first sensor unit 20A, a second sensor unit 50B, and a calculating unit. The first sensor unit 20A is configured to measure the third busbar 10C as one busbar to be measured.

The second sensor unit 50B is configured to measure one of remaining two busbars other than the one busbar to be measured. The second sensor unit 50B according to the present embodiment is configured to measure the second busbar 10B as the one of the remaining two busbars other than the one busbar to be measured.

The second sensor unit 50B is located between the one busbar to be measured and the other one of the remaining two busbars other than the one busbar to be measured. The second sensor unit 50B according to the present embodiment is located between the third busbar 10C and the first busbar 10A, which is the other one of the remaining two busbars other than the one busbar to be measured.

The second sensor unit 50B includes a third magnetism detection element 60C and a fourth magnetism detection element 60D.

The third magnetism detection element 60C and the fourth magnetism detection element 60D each have a sensitivity axis along the third direction (Z direction). Specifically, the third magnetism detection element 60C has a third sensitivity axis A3 along the third direction (Z direction). The fourth magnetism detection element 60D has a fourth sensitivity axis A4 along the third direction (Z direction).

The third magnetism detection element 60C and the fourth magnetism detection element 60D are arranged in the second direction (X direction). In the present embodiment, the third magnetism detection element 60C and the fourth magnetism detection element 60D are located at substantially same positions in the third direction (Z direction) and are arranged in the second direction (X direction).

The first magnetism detection element 30A, the second magnetism detection element 30B, the third magnetism detection element 60C, and the fourth magnetism detection element 60D are configured to detect magnetic fields generated by currents flowing through the first busbar 10A, the second busbar 10B, and the third busbar 10C.

The calculating unit calculates current values of the first busbar 10A, the second busbar 10B, and the third busbar 10C from output values of the first sensor unit 20A and the second sensor unit 50B.

A positional relationship among the busbars and the magnetism detection elements is described below. As illustrated in FIG. 7, a distance d between the third magnetism detection element 60C and the first busbar 10A (the other one of the remaining two busbars other than the one busbar to be measured) and a distance d between the fourth magnetism detection element 60D and the third busbar 10C (the one busbar to be measured) are substantially equal when viewed in the first direction (Y direction).

A distance e between the third magnetism detection element 60C and the third busbar 10C (the one busbar to be measured) and a distance e between the fourth magnetism detection element 60D and the first busbar 10A (the other one of the remaining two busbars other than the one busbar to be measured) are substantially equal when viewed in the first direction (Y direction).

The third magnetism detection element 60C and the second busbar 10B (the one of the remaining two busbars other than the one busbar to be measured) are arranged at a distance f1 from each other when viewed in the first direction (Y direction). The fourth magnetism detection element 60D and the second busbar 10B are arranged at a distance f2 from each other when viewed in the first direction (Y direction). Note that the distance f1 and the distance f2 are may be different.

In the present embodiment, the first sensor unit 20A can measure a current value (I₃) of a current flowing through the third busbar 10C. The second sensor unit 50B can measure a current value (I₂) of a current flowing through the second busbar 10B. A current value (I₁) of a current flowing through the first busbar 10A is calculated from the current values measured by the first sensor unit 20A and the second sensor unit 50B.

As in the first exemplary embodiment, the current values of the currents flowing through the busbars 10 can be calculated from a measurement value V₁ detected and calculated in the first sensor unit 20A and a measurement value V₂ calculated on the basis of a magnetic field B₂₁ detected by the third magnetism detection element 60C of the second sensor unit 50B and a magnetic field B₂₂ detected by the fourth magnetism detection element 60D of the second sensor unit 50B by the first sensor unit 20A, the second sensor unit 50B, and the calculating unit on the basis of the following expressions (8) to (14).

$$\begin{matrix}[ Math . 5 ] & \\ {B}_{21} = \frac{k}{d} {I}_{1} - \frac{k}{f 1} {I}_{2} - \frac{k}{e} {I}_{3} + {B}_{e x} & ( 8 )\end{matrix}$$

$${B}_{22} = \frac{k}{e} {I}_{1} + \frac{k}{f 2} {I}_{2} - \frac{k}{d} {I}_{3} + {B}_{e x} \qquad ( 9 )$$

$$\begin{matrix}[ Math . 6 ] & \\ \begin{matrix}{B}_{21} - {B}_{22} = \frac{k}{d} {I}_{1} - \frac{k}{f 1} {I}_{2} - \frac{k}{e} {I}_{3} + {B}_{e x} - \frac{k}{e} {I}_{1} - \frac{k}{f 2} {I}_{2} + \frac{k}{d} {I}_{3} - {B}_{e x} & ( 10 ) \\ = k ( \frac{e}{d e} {I}_{1} - \frac{f 2}{f 1 f 2} {I}_{2} 0 \frac{d}{d e} {I}_{{3}^{-}} \frac{d}{d e} {I}_{1} - \frac{f 1}{f 1 f 2} {I}_{2} + \frac{e}{d e} {I}_{3} ) & \\ = k ( \frac{e - d}{d e} {I}_{1} + \frac{- ( f 2 + f 1 )}{f 1 f 2} {I}_{2} + \frac{e - d}{d e} {I}_{3} ) & \\ = k ( \frac{e - d}{d e} {I}_{1} + \frac{- ( e - d )}{f 1 f 2} {I}_{2} + \frac{e - d}{d e} {I}_{3} ) & ( 11 ) \\ = k ( e - d ) ( \frac{1}{de} {I}_{1} - \frac{1}{f 1 f 2} {I}_{2} + \frac{1}{d e} {I}_{3} ) & \\ = k ( e - d ) ( \frac{1}{d e} ( {I}_{1} + {I}_{3} ) - \frac{1}{f 1 f 2} {I}_{2} ) & \\ = k ( e - d ) ( \frac{1}{d e} ( - {I}_{2} ) - \frac{1}{f 1 f 2} {I}_{2} ) & \\ = k ( e - d ) ( - \frac{1}{d e} - \frac{1}{f 1 f 2} ) {I}_{2} & \end{matrix} & \end{matrix}$$

$${B}_{21} - {B}_{22} ∝ {I}_{2} \qquad ( 12 )$$

$$∴ {V}_{2} ∝ {I}_{2}$$

$$\begin{matrix}[ Math . 7 ] & \\ {V}_{1} ∝ {I}_{3} & ( 13 )\end{matrix}$$

$$\begin{matrix}[ Math . 8 ] & \\ {V}_{1} + {V}_{2} ∝ {I}_{2} + {I}_{3} & ( 14 )\end{matrix}$$

$$∴ {V}_{1} + {V}_{2} ∝ {I}_{1}$$

In the current sensor 1A according to the second exemplary embodiment, the first sensor unit 20A and the second sensor unit 50B each including two magnetism detection elements are located between three-phase alternating-current busbars to measure the three-phase alternating-current busbars. The two magnetism detection elements are located so that a distance between one of the magnetism detection elements and the one of the remaining two busbars other than the one busbar to be measured and a distance between the other one of the magnetism detection elements and the other one of the remaining two busbars other than the one busbar to be measured are substantially equal. Magnetic fields generated from the currents flowing through the busbars are detected by the two magnetism detection elements, and a differential output value between the current values measured by the two magnetism detection elements is calculated by the calculating unit. In this way, a measurement value of a magnetic field detected in each sensor unit can be expressed only by a value proportional to a current value of a busbar to be measured among the busbars. Current values of the two busbars to be measured are measured by the two sensor units. A measurement value of remaining one busbar is calculated from the current values measured by the sensor units on the basis of the relationship among the three-phase alternating currents. Since a measurement value in each sensor unit can be expressed only by a current value to be measured without using a shield member that blocks an external magnetic field while canceling influence of the external magnetic field, preparations such as measuring current values of the busbars and acquiring a parameter in advance are not needed. Furthermore, complicated calculation based on the parameter is not needed. As a result, measurement accuracy and responsiveness is improved while an overall size of the current sensor 1A is reduced.

Note that it is desirable that cross-sectional areas of the first busbar, the second busbar, and the third busbar are substantially identical so that amounts of currents flowing through the first busbar, the second busbar, and the third busbar are easily made uniform.

In the description of the above embodiments, combinable configurations may be combined with each other.

In general, it is noted that the exemplary embodiments disclosed herein are illustrative in all respects and should not be construed as being restrictive.

### REFERENCE SIGNS LIST

1,1A current sensor
10A first busbar
10B second busbar
10C third busbar
20A first sensor unit
20B, 50B second sensor unit
30A first magnetism detection element
30B second magnetism detection element
30C, 60C third magnetism detection element
30D, 60D fourth magnetism detection element
31 tunnel magneto resistance element
32A first amplifier
32B second amplifier
32C third amplifier
32D fourth amplifier
40 calculating unit
41A first differential amplifier
41B second differential amplifier
42 summing amplifier
A1 first sensitivity axis
A2 second sensitivity axis
A3 third sensitivity axis
A4 fourth sensitivity axis
F virtual plane

1. A current sensor comprising:
a first busbar, a second busbar, and a third busbar that extend in a first direction apart from each other and are arranged in a second direction that is orthogonal to the first direction and through which three-phase alternating currents flow;
a first sensor unit that is located between two busbars other than one busbar to be measured among the first, second and third busbars;
a second sensor unit configured to measure one of a remaining two busbars other than the one busbar to be measured and is located between the one busbar to be measured and another one of the remaining two busbars other than the one busbar to be measured; and
a calculating unit configured to calculate current values of the first busbar, the second busbar, and the third busbar based on output values from the first sensor unit and the second sensor unit,
wherein the first sensor unit includes a first magnetism detection element and a second magnetism detection element that each have a sensitivity axis along a third direction orthogonal to the first direction and the second direction and that are arranged in the second direction and configured to detect magnetic fields generated by currents flowing through the first, second and third busbars,
wherein the second sensor unit includes a third magnetism detection element and a fourth magnetism detection element that each have a sensitivity axis along the third direction and that are arranged in the second direction and configured to detect magnetic fields generated by the currents flowing through the first, second and third busbars,
wherein a distance between the first magnetism detection element and the one of the remaining two busbars other than the one busbar to be measured and a distance between the second magnetism detection element and the other one of the remaining two busbars other than the one busbar to be measured are substantially equal when viewed in the first direction,
wherein a distance between the third magnetism detection element and the other one of the remaining two busbars other than the one busbar to be measured and a distance between the fourth magnetism detection element and the one busbar to be measured are substantially equal when viewed in the first direction, and
wherein the calculating unit is configured to calculate:
a current value of a current flowing through the one busbar to be measured based on a differential output value between a measurement value of the first magnetism detection element of the first sensor unit and a measurement value of the second magnetism detection element of the first sensor unit,
a current value of a current flowing through the one of the remaining two busbars other than the one busbar to be measured based on a differential output value between a measurement value of the third magnetism detection element of the second sensor unit and a measurement value of the fourth magnetism detection element of the second sensor unit, and
a current value of a current flowing through the other one of the remaining two busbars other than the one busbar to be measured by adding up the current value of the current flowing through the one busbar to be measured and the current value of the current flowing through the one of the remaining two busbars other than the one busbar to be measured.

2. The current sensor according to claim 1, wherein the first sensor unit and the second sensor unit each comprise a tunnel magneto resistance element.

3. The current sensor according to claim 1, wherein the first sensor unit and the second sensor unit each comprise a giant magneto resistance element.

4. The current sensor according to claim 1, wherein the first sensor unit and the second sensor unit each comprise an anisotropic magneto resistance element.

5. The current sensor according to claim 1, wherein the first sensor unit and the second sensor unit each comprise a Hole element.

6. The current sensor according to claim 1, wherein the first busbar, the second busbar, the third busbar, the first sensor unit, and the second sensor unit are each disposed on a virtual plane along the first direction and the second direction.

7. The current sensor according to claim 1, wherein a distance in the second direction between the second busbar and the third busbar is equal to a distance in the second direction between the first busbar and the second busbar.

8. The current sensor according to claim 1, wherein the first magnetism detection element, the second magnetism detection element, the third magnetism detection element, and the fourth magnetism detection element each include a Wheatstone bridge circuit that comprises four tunnel magneto resistance elements.

9. The current sensor according to claim 1, wherein each of the first busbar, the second busbar, the third busbar, the first sensor unit and the second sensor unit do not include a shield member covering the respective busbar and sensor unit.

10. The current sensor according to claim 1, wherein each of the first busbar, the second busbar, and the third busbar has a cross-sectional area that is substantially identical to one another.

11. A current sensor comprising:
a first busbar, a second busbar, and a third busbar that extend in a first direction apart from each other and are arranged in order in a second direction that is orthogonal to the first direction;
a first sensor unit that is located between the first and second busbars and is configured to generate an output value based on a measurement of the third busbar;
a second sensor unit that is located between the second and third busbars and is configured to generate an output value based on a measurement of the first busbar;
a calculating unit configured to calculate current values of the first busbar, the second busbar, and the third busbar based on generated output values from the first sensor unit and the second sensor unit,
wherein the first sensor unit includes a first magnetism detection element and a second magnetism detection element that each have a sensitivity axis along a third direction orthogonal to the first direction and the second direction and that are arranged in the second direction and configured to detect magnetic fields generated by currents flowing through the first, second and third busbars,
wherein the second sensor unit includes a third magnetism detection element and a fourth magnetism detection element that each have a sensitivity axis along the third direction and that are arranged in the second direction and configured to detect magnetic fields generated by the currents flowing through the first, second and third busbars,
wherein a distance between the first magnetism detection element and the second busbar and a distance between the second magnetism detection element and the first busbar are substantially equal when viewed in the first direction,
wherein a distance between the third magnetism detection element and the third busbar and a distance between the fourth magnetism detection element and the second busbar are substantially equal when viewed in the first direction.

12. The current sensor according to claim 11, wherein the calculating unit is configured to calculate:
a current value of a current flowing through the third busbar based on a differential output value between a measurement value of the first magnetism detection element of the first sensor unit and a measurement value of the second magnetism detection element of the first sensor unit,
a current value of a current flowing through the first busbar based on a differential output value between a measurement value of the third magnetism detection element of the second sensor unit and a measurement value of the fourth magnetism detection element of the second sensor unit, and
a current value of a current flowing through the second busbar by adding up the current value of the current flowing through the first busbar and the current value of the current flowing through the third busbar.

13. The current sensor according to claim 11, wherein the first sensor unit and the second sensor unit each comprise a tunnel magneto resistance element.

14. The current sensor according to claim 11, wherein the first sensor unit and the second sensor unit each comprise a giant magneto resistance element.

15. The current sensor according to claim 11, wherein the first sensor unit and the second sensor unit each comprise an anisotropic magneto resistance element.

16. The current sensor according to claim 11, wherein the first sensor unit and the second sensor unit each comprise a Hole element.

17. The current sensor according to claim 11, wherein the first busbar, the second busbar, the third busbar, the first sensor unit, and the second sensor unit are each disposed on a virtual plane along the first direction and the second direction.

18. The current sensor according to claim 11, wherein a distance in the second direction between the second busbar and the third busbar is equal to a distance in the second direction between the first busbar and the second busbar.

19. The current sensor according to claim 11, wherein the first magnetism detection element, the second magnetism detection element, the third magnetism detection element, and the fourth magnetism detection element each include a Wheatstone bridge circuit that comprises four tunnel magneto resistance elements.

20. The current sensor according to claim 11, wherein each of the first busbar, the second busbar, the third busbar, the first sensor unit and the second sensor unit do not include a shield member covering the respective busbar and sensor unit.
